(19) United States
(12) Patent Application Publication
(10) Pub. No.: US 2025/0208482 A1
(43) Pub. Date: Jun. 26, 2025

(54) THROUGH SILICON VIA FOR THIN FILM LITHIUM-CONTAINING ELECTRO-OPTIC DEVICES

(71) Applicant: HyperLight Corporation, Cambridge, MA (US)

(72) Inventors: Christian Reimer, Wellesley, MA (US); Mian Zhang, Cambridge, MA (US)

(21) Appl. No.: 18/991,039

(22) Filed: Dec. 20, 2024

Related U.S. Application Data
(60) Provisional application No. 63/613,588, filed on Dec. 21, 2023.

(51) Int. Cl. G02F 1/355; G02F 1/365; H01L 25/16

(52) U.S. Cl. CPC G02F 1/3551; G02F 1/365; H01L 25/167; G02F 2201/42

(57) ABSTRACT

An electro-optic device is described. The electro-optic device includes a substrate, an oxide layer and a thin film lithium-containing (TFLC) electro-optic layer. The oxide layer is on the substrate. The TFLC electro-optic layer is on the oxide layer. The TFLC electro-optic layer includes a waveguide. The electro-optic device also includes a via extending through the substrate, the oxide layer, and the TFLC electro-optic layer. The via includes a conductive filler.

### CROSS REFERENCE TO OTHER APPLICATIONS

This application claims priority to U.S. Provisional Patent Application No. 63/613,588 entitled THROUGH SILICON VIA FOR THIN FILM LITHIUM-CONTAINING ELECTRO-OPTIC DEVICES filed Dec. 21, 2023 which is incorporated herein by reference for all purposes.

### BACKGROUND OF THE INVENTION

Thin film lithium-containing (TFLC) electro-optic materials include thin film lithium niobate (TFLN) and thin film lithium tantalate (TFLT). TFLC materials may have a large modulation in the index of refraction for a given applied electric field. This large response is desirable. Consequently, TFLC materials are desired to be used within electro-optic devices. TFLC-containing electro-optic devices are desired to be integrated with other photonics devices as well as other integrated circuits. For example, telecommunication and/or data communication may benefit from the large modulation in TFLC electro-optic modulators. To be used in such applications, the TFLC electro-optic device may be driven by an electrical signal. In some cases, the TFLC electro-optic device (i.e., TFLC integrated circuit or TFLC photonics device) is placed on a printed circuit board (PCB) and wire bonded to make electrical connection to the electrodes in the TFLC electro-optic device. Integration may include placing other components on the PCB and providing optical and/or electrical connection to the components. An integrated device may thus be obtained.

Although integration of lithium-containing TFLC devices with other technologies is possible, sacrifices in the desired performance are made to achieve integration. Therefore, additional techniques for integrating the TFLC device are desired.

### BRIEF DESCRIPTION OF THE DRAWINGS

Various embodiments of the invention are disclosed in the following detailed description and the accompanying drawings.

FIGS. 1A-1D depict an embodiment of an electro-optic device that may have improved integration.

FIG. 2 depicts an embodiment of an electro-optic device that may have improved integration as mounted on a substrate.

FIG. 3 depicts an embodiment of an electro-optic device integrated with additional component(s).

FIG. 4 depicts an embodiment of an electro-optic device integrated with additional component(s).

FIG. 5 depicts an embodiment of an electro-optic device integrated with an additional component.

FIG. 6 depicts an embodiment of an electro-optic device integrated with an additional component.

FIG. 7 is a flow-chart depicting an embodiment of a method for providing an electro-optic device and integrating the electro-optic device integrated with an additional component(s).

### DETAILED DESCRIPTION

The invention can be implemented in numerous ways, including as a process; an apparatus; a system; a composition of matter; a computer program product embodied on a computer readable storage medium; and/or a processor, such as a processor configured to execute instructions stored on and/or provided by a memory coupled to the processor. In this specification, these implementations, or any other form that the invention may take, may be referred to as techniques. In general, the order of the steps of disclosed processes may be altered within the scope of the invention. Unless stated otherwise, a component such as a processor or a memory described as being configured to perform a task may be implemented as a general component that is temporarily configured to perform the task at a given time or a specific component that is manufactured to perform the task. As used herein, the term ‘processor’ refers to one or more devices, circuits, and/or processing cores configured to process data, such as computer program instructions.

A detailed description of one or more embodiments of the invention is provided below along with accompanying figures that illustrate the principles of the invention. The invention is described in connection with such embodiments, but the invention is not limited to any embodiment. The scope of the invention is limited only by the claims and the invention encompasses numerous alternatives, modifications and equivalents. Numerous specific details are set forth in the following description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured.

Electro-optic devices that include thin film lithium-containing (TFLC) electro-optic materials, such as film lithium niobate (TFLN) and/or thin film lithium tantalate (TFLT), are desirable for use in a number of applications. TFLC electro-optic devices are also desired to be integrated with other components. For example, a TFLC electro-optic device may be placed on a printed circuit board (PCB) and wire bonded to make electrical connection. Other components may also be placed on the PCB and electrical connection made to such components. Optical electrical connection is also provided to the TFLC electro-optic device. Moreover, other component may be desired to be mounted on the TFLC electro-optic device or otherwise integrated into the final device.

Although integration of lithium-containing TFLC devices with other technologies is possible, sacrifices in the desired performance are made to achieve integration. For example, wire bonding may utilize pads that have dimensions on the order of one hundred and fifty micrometers. Thus, wire bonding pads consume a large amount of area. Wire bonding may also not be as robust as desired. It has also been determined that conventional techniques for integrating the TFLC electro-optic device, such as flip-chip bonding, may adversely affect performance. Flip-chip bonding is often used in advanced packaging including 2.5D packaging. In flip-chip bonding, one integrated circuit is flipped on top of another integrated circuit or substrate. Electrical connection is usually achieved using solder balls (bumping) and capillary underfill to fill the gap between the integrated circuits and fix the integrated circuit in place.

For a TFLC electro-optic device, the electrodes are formed at or near the top surface of the electro-optic device. During use, these electrodes may carry an electrode signal (e.g., the electrode signal may be used to modulate the optical mode carried in a TFLC waveguide). The electrode signal may have a frequency in the microwave range. For example, the frequency of the electrode signal may be as high as 10 GHz, 100 GHz, 200 GHz, or more. The microwave mode of the electrode signal extends outside of the electrodes. Because of the location of the electrodes, the microwave mode may extend outside of the TFLC electro-optic device. As a result, the microwave mode of the TFLC electro-optic device may interfere with other components with which the TFLC electro-optic device is desired to be flip-chip bonded. Thus, performance of these other components may be adversely affected.

In addition, it has been determined that an underfill or other material placed between the TFLC electro-optic device and the remaining component(s) may interact with the microwave mode. Interactions of the microwave mode with the underfill and/or the component with which the TFLC electro-optic device is to be flip-chip bonded adversely affects performance of the TFLC electro-optic device. For example, the velocity of the microwave signal in the TFLC electro-optic device electrodes, RF losses, and the impedance of the electrodes may be affected. Performance of the TFLC electro-optic device may suffer. Thus, flip-chip bonding may be challenging to achieve for TFLC electro-optic devices without adversely affecting performance of the TFLC electro-optic device and/or other components. Consequently, additional techniques for integrating TFLC electro-optic devices are desired.

An electro-optic device is described. The electro-optic device includes a substrate, an oxide layer and a thin film lithium-containing (TFLC) electro-optic layer. The oxide layer is on the substrate. The TFLC electro-optic layer is on the oxide layer. The TFLC electro-optic layer includes a waveguide. The electro-optic device also includes a via extending through the substrate, the oxide layer, and the TFLC electro-optic layer. The via includes a conductive filler. For example the conductive filler might include coper, gold, and/or platinum. In some embodiments, the oxide layer is at least three micrometers thick and not more than fifteen micrometers thick. In some embodiments, the oxide layer is at least four micrometers thick. The oxide layer may be not more than ten micrometers thick. In some embodiments, the TFLC electro-optic layer extends across a portion of the oxide layer. In some embodiments, the TFLC electro-optic layer extends across the oxide layer.

The electro optic device may further include an electrode that is electrically coupled with the conductive filler in the via. In some embodiments, the substrate is mounted on an additional substrate that includes a conductive pad. The conductive filler is electrically connected to the conductive pad.

In some embodiments, an integrated circuit (IC) is mounted on the electro-optic device such that the oxide layer is between the substrate and the IC. The IC is electrically connected to the conductive filler. In some such embodiments, the IC includes a driver IC and/or a photodiode. The IC is the photodiode in some embodiments. The photodiode may be an edge-illuminated photodiode. In such embodiments, the via has a top portion configured to receive the photodiode. At least part of the top portion of the via is free of the conductive filler. The photodiode is in the top portion of the via. The IC is a back-coupled photodiode in some embodiments. In such embodiments, the photodiode is on the electro-optic device.

An electro-optic device including a substrate, an oxide layer, a TFLC electro-optic layer, and a via is also described. The substrate is a silicon substrate having a substrate thickness of at least one hundred micrometers. The oxide layer is on the substrate layer. The oxide layer is a silicon dioxide layer having a thickness of at least three micrometers and not more than ten micrometers. In some embodiments, the oxide layer is at least four micrometers thick. The oxide layer may be not more than ten micrometers thick. The TFLC electro-optic layer is on at least a portion of the oxide layer. The TFLC electro-optic layer includes a waveguide. The via extends through the substrate, the oxide layer, and the TFLC electro-optic layer. The via includes a conductive filler. The electro-optic device may be mounted on an additional substrate having an electrical connection. The electro-optic device is electrically connected to the electrical connection by the conductive filler. In some embodiments, the electro-optic device further includes an electrode electrically coupled with the conductive filler. In some embodiments, at least one IC is mounted on the electro-optic device such that the oxide layer is between the substrate and the IC. The IC is electrically connected to the conductive filler. The IC may include a driver IC and/or a photodiode. For the IC being a photodiode, the photodiode may be an edge-illuminated photodiode. In such embodiments, the via has a top portion configured to receive the photodiode. At least part of the top portion of the via is free of the conductive filler. The photodiode resides in the top portion of the via. In some embodiments, multiple vias (at least some of which have conductive filler) are coupled to the photodiode. In such embodiments, the vias may be arranged such that there is an area that does not contain a conductive filler, allowing light to be coupled into the photodiode. In various embodiments, the optical path of the light to the photodiode may or may not include underfill.

A method is described. The method includes providing an electro-optic device including a substrate, an oxide layer on the substrate, and a TFLC electro-optic layer on the oxide layer. The TFLC electro-optic layer includes a waveguide. The method also includes providing a via extending through the substrate, the oxide layer, and the TFLC electro-optic layer. The via includes a conductive filler. In some embodiments, providing the via further includes forming the via after the waveguide is provided form the TFLC layer. In some embodiments, providing the via includes forming the via before the waveguide is provided form the TFLC layer. In some embodiments, the method also includes mounting the electro-optic device on an additional substrate including a conductive pad such that the conductive filler is electrically connected to the conductive pad. An IC may be mounted on the electro-optic device such that the oxide layer is between the substrate and the IC. The IC is electrically connected to the conductive filler. Forming the via may include forming a top portion configured to receive the IC. In some such embodiments, at least part of the top portion of the via is free of the conductive filler. The IC is in the top portion of the via.

Various features of the electro-optic devices are described herein. One or more of these features may be combined in manners not explicitly described herein. The optical devices described herein may be formed using electro-optic materials, such as thin film lithium containing (TFLC) electro-optical materials. For example, thin film lithium niobate (TFLN) and/or thin film lithium tantalate (TFLT) may be used for the components described. Although primarily described in the context of TFLC electro-optic materials, such as TFLN and TFLT, other nonlinear optical materials may be used in the optical devices described herein. For example, other ferroelectric nonlinear (e.g. second order) optical materials may also be desired to be used in, e.g., waveguides, modulators, polarization rotators, and/or mode converters. Such ferroelectric nonlinear optical materials may include but are not limited to potassium niobate (e.g. KNbO₃), gallium arsenide (GaAs), potassium titanyl phosphate (KTP), lead zirconate titanate (PZT), and barium titanate (BaTiO₃). The techniques described may also be used for other nonlinear ferroelectric optical materials, particularly those which may otherwise be challenging to fabricate. For example, such nonlinear ferroelectric optical materials may have inert chemical etching reactions using conventional etching chemicals such as fluorine, chlorine or bromine compounds.

In some embodiments, the optical material(s) used are nonlinear. As used herein, a nonlinear optical material exhibits the electro-optic effect and has an effect that is at least (e.g. greater than or equal to) 5 picometer/volt. In some embodiments, the nonlinear optical material has an effect that is at least 10 picometer/volt. In some such embodiments nonlinear optical material has an effect of at least 20 picometer/volt. The nonlinear optical material experiences a change in index of refraction in response to an applied electric field. In some embodiments, the nonlinear optical material is ferroelectric. In some embodiments, the electro-optic material effect includes a change in index of refraction in an applied electric field due to the Pockels effect. Thus, in some embodiments, optical materials possessing the electro-optic effect in one or more the ranges described herein are considered nonlinear optical materials regardless of whether the effect is linearly or nonlinearly dependent on the applied electric field. The nonlinear optical material may be a non-centrosymmetric material. Therefore, the nonlinear optical material may be piezoelectric. Such nonlinear optical materials may have inert chemical etching reactions for conventional etching using chemicals such as fluorine, chlorine or bromine compounds. In some embodiments, the nonlinear optical material(s) include one or more of LN, LT, potassium niobate, gallium arsenide, potassium titanyl phosphate, lead zirconate titanate, and barium titanate. In other embodiments, other nonlinear optical materials having analogous optical characteristics may be used.

In some embodiments, waveguides and other structures described herein are low optical loss optical structures. For example, a waveguide may have a total optical loss of not more than 10 dB through the portion of waveguide (e.g. when biased at maximum transmission and as a maximum loss) in proximity to electrodes used in modulating the optical signal. The total optical loss is the optical loss in a waveguide through a single continuous electrode region (e.g. as opposed to multiple devices cascaded together). In some embodiments, the waveguide has a total optical loss of not more than 8 dB. In some embodiments, the total optical loss is not more than 4 dB. In some embodiments, the total optical loss is less than 3 dB. In some embodiments, the total optical loss is less than 2 dB. In some embodiments, the waveguide has an optical loss of not more than 3 dB/cm (e.g. on average). In some embodiments, the nonlinear material(s) in the waveguides has an optical loss of not more than 2.0 dB/cm. In some such embodiments, the waveguide has an optical loss of not more than 1.0 dB/cm. In some embodiments, the waveguide has an optical loss of not more than 0.5 dB/cm. In some embodiments, the low optical losses are associated with a low surface roughness of the side walls of the waveguides.

The waveguides and other optical structures may have improved surface roughness. For example, the short range root mean square surface roughness of a sidewall of the rib may be less than ten nanometers. In some embodiments, this root mean square surface roughness is not more than five nanometers. In some cases, the short range root mean square surface roughness does not exceed two nanometers. In some embodiments, a waveguide includes a rib portion and a slab portion. The height of such a rib portion is selected to provide a confinement of the optical mode such that there is a 10 dB reduction in intensity from the intensity at the center of the rib at ten micrometers from the center of the rib. For example, the height of the rib is on the order of a few hundred nanometers in some cases. However, other heights are possible in other embodiments. Various other optical components may be incorporated into the waveguide to provide the desired functionality. For example, the waveguide may have wider portion(s) for accommodating multiple modes or performing other functions.

The improved surface roughness of waveguides (and other structures described herein) formed of TFLC electro-optic material(s) may be fabricated utilizing photolithography. For example, ultraviolet (UV) and/or deep ultraviolet (DUV) photolithography may be used to pattern masks for the nonlinear optical material. For DUV photolithography, the wavelength of light used is typically less than two hundred and fifty nanometers. To fabricate the waveguide, the thin film nonlinear optical material may undergo a physical etch, for example using dry etching, reactive ion etching (RIE), inductively coupled plasma RIE. In some embodiments, a chemical etch and/or electron beam etch may be used. Waveguide and other structures formed of the electro-optic material(s) may have improved surface roughness.

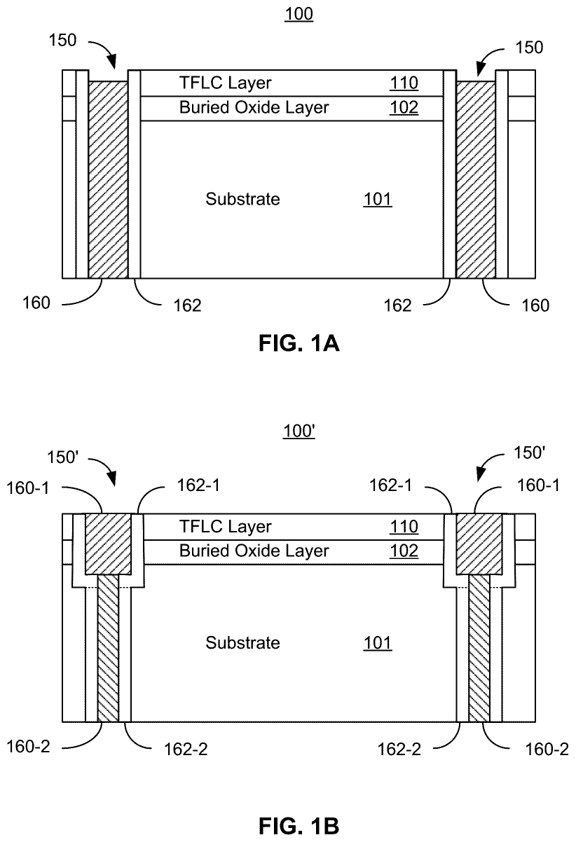

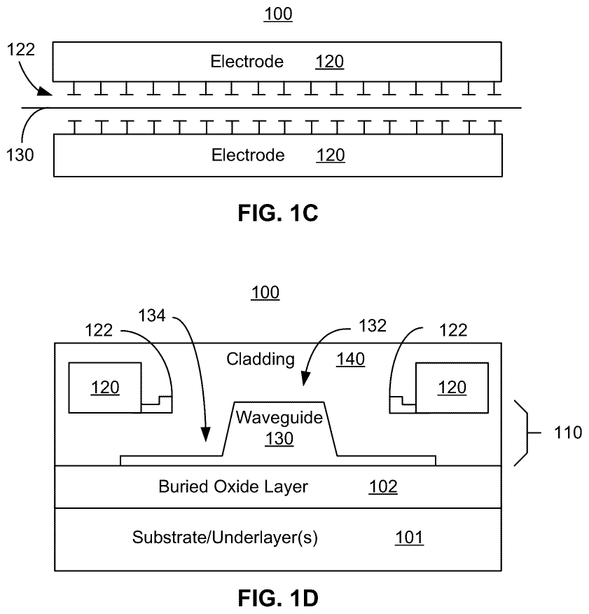

FIGS. 1A-1D depict embodiments of electro-optic device 100 that may have improved integration. FIG. 1A depicts a side view of the entire device 100. FIG. 1B depicts a side view of another device 100′ (or another portion of device 100). FIG. 1C depicts a plan view of a portion of electro-optic device 100. FIG. 1D depicts a cross-sectional view of a portion of electro-optic device 100. FIGS. 1A-1D are not to scale. For clarity, only some components are shown.

Electro-optic device 100 includes waveguide 130 and electrodes 120 residing on a substrate structure including substrate 101 and buried oxide (BOX) layer 102. Also shown is cladding 140, which may be or include silicon dioxide. In some embodiments, substrate 101 is a silicon substrate. Such a silicon substrate may be at least fifty micrometers thick. Silicon substrate 101 may be at least eighty micrometers thick. In some embodiments, substrate 101 is at least one hundred micrometers thick. Generally, substrate 101 is not more than one hundred and fifty micrometers or two hundred micrometers thick. Such a substrate thickness may be desired for mechanical stability and robustness of substrate 101. Further, in some embodiments, substrate 101 has been thinned during fabrication of electro-optic device 100. BOX layer 102 may include or consist of silicon dioxide. In some embodiments, BOX layer 102 is at least two micrometers thick and not more than twenty micrometers thick. BOX layer 102 may be at least three micrometers thick and not more than fifteen micrometers thick. In some embodiments, BOX layer 102 may be at least four micrometers thick. BOX layer 102 may be not more than ten micrometers thick. Although shown as a single layer, BOX layer 102 may include multiple layers. In some embodiments, other material(s) and/or other thicknesses may be used for substrate 101 and/or BOX layer 102. For example, quartz and/or another material might be used for substrate 102.

Electro-optic device 100 also includes an electro-optic layer 110. Electro-optic layer 110 includes one or more TFLC materials, such as TFLN and/or TFLT. In some embodiments, other electro-optic material(s) may be used may be used in addition to or in lieu of TFLC material(s). Although described as a layer, TFLC layer may include multiple layers. Thus, electro-optic device 100 is described in the context of TFLC layer 110. TFLC layer has been processed or formed such that waveguide 130 is formed therein.

Waveguide 130 includes ridge portion 132 and thin film, or slab, portion 134. Waveguide 130 may be formed by etching thin TFLC layer 110. For example, the thickness of the electro-optic layer(s) form which waveguide 130 is formed is not more than three micrometers prior to fabrication of waveguide 130. In some embodiments, this thickness is not more than 1.5 micrometer or not more than one micrometer. In some embodiments, the thickness is not more than seven hundred nanometers or not more than five hundred nanometers. In some embodiments, the thickness is at least one hundred nanometers. Other thicknesses are possible. The thickness of waveguides 130 is less than or equal to the thickness of the as-provided electro-optic layer. For example, the thickness of waveguides 130 may be on the order of a few hundred nanometers (e.g. 100-300 nanometers) or less. Other thicknesses are possible.

In the embodiment shown, electrodes 120 may include extensions 122. Embodiments of analogous electrodes may be found in co-pending U.S. patent application Ser. No. 17/843,906, entitled ELECTRO-OPTIC DEVICES HAVING ENGINEERED ELECTRODES, which is a continuation of U.S. patent application Ser. No. 17/102,047 entitled ELECTRO-OPTIC DEVICES HAVING ENGINEERED ELECTRODES, filed Nov. 23, 2020, which claims priority to U.S. Provisional Patent Application No. 62/941,139 entitled THIN-FILM ELECTRO-OPTIC MODULATORS filed Nov. 27, 2019, U.S. Provisional Patent Application No. 63/033,666 entitled HIGH PERFORMANCE OPTICAL MODULATORS filed Jun. 2, 2020, and U.S. Provisional Patent Application No. 63/112,867 entitled BREAKING VOLTAGE-BANDWIDTH LIMIT IN INTEGRATED LITHIUM NIOBATE MODULATORS USING MICRO-STRUCTURED ELECTRODES filed Nov. 12, 2020, all of which are incorporated herein by reference for all purposes. In other embodiments, extensions 122 may be omitted. Electrodes 120 may carry differential electrical signals, a single electrical signal (e.g. a signal and ground), or other signal(s).

Although described in the context of waveguide 130 and electrodes 120, other and/or additional components are generally present in electro-optic device 100. For example, additional electrodes and waveguide arms (e.g. in a Mach-Zehnder modulator configuration) as well as other passive and/or active components may be present. For example, mode converter(s), input/output coupler(s), polarization rotation components, and/or other optical, electrical, and/or other components may be present. However, at least some of these components may be considered part of TFLC layer 110.

Electro-optic device 100 also includes vias 150 having conductive fill 160 and optional dielectric coating 162. Although two vias 150 having particular locations are shown, another (e.g., larger) number of vias are generally present and may be located as desired for electro-optic device 100. In some embodiments, vias 150 are through-silicon vias (TSVs). Vias 150 extend through not only substrate 101, but also BOX layer 102 and TFLC layer 110. For example, a portion of TFLC layer 110 may be removed as part of the formation of vias 150. In some embodiments, portions of TFLC layer 110 may be removed for other purposes (e.g. to terminate thin film portion 134 closer to ridge portion 132 of waveguide 130) in the location of one or more vias 150. However, such vias 150 are still considered to extend through TFLC layer 110 because the TFLC layer 110 is not present in the region of the vias 150. Further, although shown with particular shapes, vias 150 may have different shapes. Such shapes may depend, for example, on how such vias are formed.

Conductive filler 160 is shown as terminating below the top of via 150. In some embodiments, conductive filler 160 fills via 150. In some embodiments, conductive filler 160 may not fill the region to the top of electro-optic device 100. However, conductive filler 160 is configured to make electrical contact with the desired component(s). In some embodiments, conductive filler 160 may include one or more metals, such as copper, gold, aluminum and/or platinum. Other conductors may be used in some embodiments. Thus, multiple conductive fillers 160′ might be mixed in a single via 150.

Dielectric coating 162 may be silicon dioxide or another insulator. Dielectric coating 162 may reduce radio frequency (RF) losses for high frequency signals driven through vias 150. Thus, dielectric 162 may be desirable for higher frequency signals, for example at least 50 GHz, at least 100 GHz, or more. In addition, dielectric coating 162 insulates portions of electro-optic device 100 adjacent to vias 150 from conductive filler 160. For example, substrate 101 (which may be a semiconductor such as Si) may be electrically insulated from conductive filler 160. In some embodiments, dielectric coating 162 coats the entire interior surface of a via 150. In some embodiments, dielectric coating 162 may coat only a portion of the interior surface of a via 150. For example, dielectric coating 162 may be omitted adjacent to BOX layer 102.

In some embodiments, formation of vias 150 may be a front end process (e.g. before formation of waveguide 130, electrodes 102, and/or other analogous optical and electrical components of electro-optic device 100), a back end process (e.g. after formation of waveguide 130, electrodes 102, and/or other analogous optical and electrical components of electro-optic device 100), or a mixture of processes. For example, a portion of BOX layer 102 and/or a portion of TFLN layer 110 for vias 150 may be removed as a front end process, while removal of a portion of substrate 101 for vias 150 may be a back end process. Removal of a portion of BOX layer 102 and/or formation of the entire vias 150 may be desirable as a front end process to allow for issues with fabrication of vias 150 to be uncovered early in the fabrication process.

Vias may have different shape(s) and/or may have other conductive filler(s). For example, FIG. 1B depicts electro-optic device 100′ in which vias 150′ have a different shape. Substrate 101, BOX layer 102, and TFLC layer 110 of electro-optic device 100′ are analogous to substrate 101, BOX layer 102, and TFLC layer 110 of electro-optic device 100. Vias 150′, conductive filler 160-1 and 160-2 (collectively or generically conductive filler 160′), and dielectric 162-1 and 162-2 (collectively or generically 162′) are analogous to vias 150, conductive filler 160, and dielectric 162, respectively. However, different portions of vias 150′ include different conductive fillers 160′ and, in some embodiments, dielectrics 162′. Vias 150′ may be formed partially through a front end process and partially through a back end process. For example, vias 150′ may be formed by a front end etch down through TFLC layer 110 and BOX layer 102 to (or through only a portion of) substrate 101. Dielectric 162-1 may be provided or may be omitted. Metallization 160-1, such as aluminum, may also be provided at the front end. Later, a back end process may be performed to complete vias 150′. More specifically, a remaining portion of vias 150′ may be provided through substrate 101 from the back side (bottom in FIG. 1B). The back (bottom) portion of vias 150 may terminate on the aluminum 160-1. In some embodiments, dielectric 162-2 is provided and the center portion re-opened to allow for electrical connection to conductive filler 160-1. However, dielectric 162-2 may be omitted. Conductive filler 160-2 is provided. Conductive filler 160-2 makes electrical contact with conductive filler 160-1. Conductive filler 160-2 may be the same as or different from conductive filler 160-1. For example, conductive filler 160-2 might be aluminum or silver. Thus, a single via 150′ that goes through the silicon substrate 101, BOX layer 102, and TFLC layer is formed. However, different conductive filler may be used in different portions of vias 150′.

Electro-optic device(s) 100 and/or 100′ may be more readily integrated. More specifically, electro-optic device 100 and/or 100′ may be electrically connected to other components, such as a printed circuit board (PCB), through conductive filler 160 and/or 160′ in vias 150 and/or 150′. For example, solder bumps (not shown in FIGS. 1A-1D) on the back side (i.e. the side opposite to TFLC layer 110) of electro-optic device 100 may be used. As a result, wire bonding need not be used for electrically connecting to electro-optic device 100 and/or 100′. Solder bumps may be significantly smaller than wire bond pads. Thus, integration of electro-optic device(s) 100 and/or 100′ may be more dense. Further, electro-optic device 100 and/or 100′ need not be flip-chip bonded in order to be electrically connected to such a substrate. As a result, electrodes 120 may be distal from the underlying component(s). Operation of electro-optic device 100 and/or 100′ may be less likely to affect and/or be affected by components on the underlying substrate. Consequently, performance of electro-optic device 100 and/or 100′ and of the package into which electro-optic device 100 and/or 100′ is being integrated may be improved. Vias 150 and/or 150′ and conductive filler 160 and/or 150′ may also facilitate 2.5 and 3D packaging for electro-optic device 100. Thus, multiple integrated circuits, including electro-optic device 100 and/or 100′, may be stacked using solder balls and vias (e.g. vias 150/150′ and conductive filler 160/160′) without requiring wire bonding. Thus, higher density integration of electro-optic device 100 and/or 100′ may be facilitated.

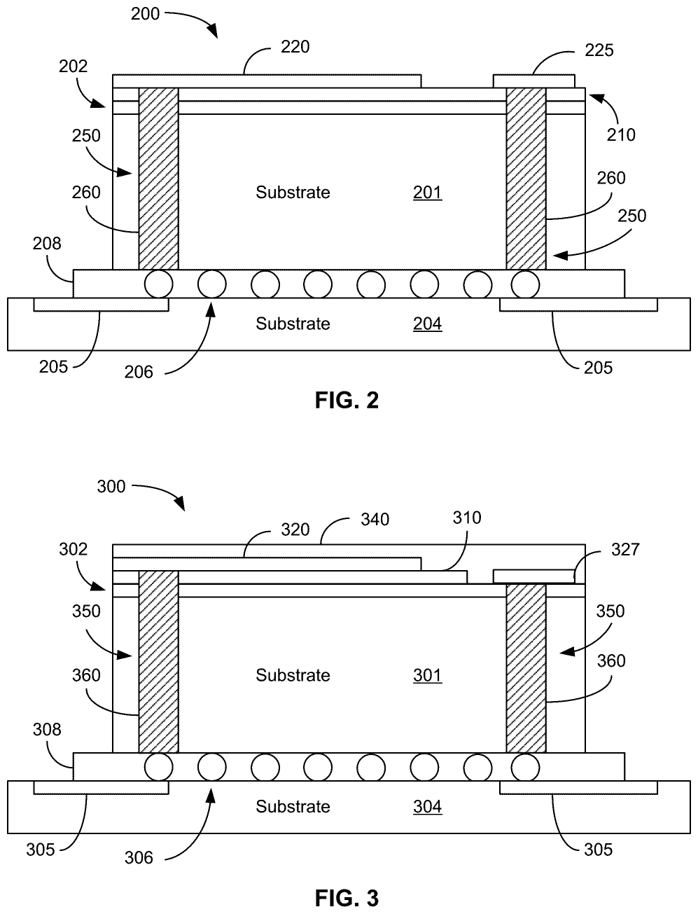

FIG. 2 depicts a side view of electro-optic device 200 and the environment in which electro-optic device 200 is integrated. FIG. 2 is not to scale. For clarity, only some components are shown. Electro-optic device 200 is analogous to electro-optic device(s) 100 and/or 100′. Electro-optic device 200 includes TFLC layer 210, electrodes 220, and a substrate structure including substrate 201 and buried oxide (BOX) layer 202 that are analogous to TFLC layer 110, electrodes 120, substrate 101, and BOX layer 102, respectively. Thus, electro-optic layer 210 includes one or more TFLC materials, such as TFLN and/or TFLT. In some embodiments, other electro-optic material(s) may be used may be used in addition to or in lieu of TFLC material(s). Although described as a layer, TFLC layer may include multiple layers. Optical components, such as waveguide(s), are formed in electro-optic layer 230.

Electro-optic device 200 also includes vias 250 having conductive fill 260 that are analogous to vias 150 and/or 150′ and conductive fill 160 and/or 160′. Although not shown, one or more of vias 250 may include a dielectric coating analogous to dielectric coating 162 and/or 162′. Although two vias 250 having particular locations are shown, another (e.g., larger) number of vias are generally present and may be located as desired for electro-optic device 200. Vias 250 extend through not only substrate 201, but also BOX layer 202 and TFLC layer 210. Further, vias 250 may be formed in an analogous manner to vias 150.

Also shown in FIG. 2 is substate 204. Substrate 204 may be a PCB or other substrate with which electro-optic device 200 is desired to be integrated. In other embodiments, substrate 204 may be another (e.g. larger) integrated circuit that electro-optic device 200 is desired to be coupled to. Substrate 204 includes pads 205 that are electrically coupled to electro-optic device 200 via solder balls 206 (of which only one is labeled) and conductive filler 260 of vias 250. Underfill 208 fills the gaps between solder bumps 206, substrate 204, and electro-optic device 200. Consequently, components (not shown) within, on, or electrically connected to substrate 204, may be electrically connected to electro-optic device 200. Thus, electro-optic device 200 is electrically and mechanically integrated with substrate 204.

Vias 250 and conductive filler 260 electrically connect electrodes 220 and structure 225 with pads 205. Thus, electrodes 220 may be driven through via 250/conductive filler 260 and substrate 260. In some embodiments, therefore, via 250 for electrodes 220 may be desired to include a dielectric coating to mitigate high frequency losses. In some embodiments, structure 225 may be a low frequency (or DC) heater (e.g., a resistor). In such embodiments, structure 225 may provide a DC phase shift. For example, a low frequency signal may be provided through conductive filler 260 coupled to structure 225 to provide a constant, or controlled, temperature. Thus, in some embodiments, a dielectric coating may not be desired for via 250 connecting to structure 225. However, such a dielectric coating may still be provided. In some embodiments, structure 225 may be or include other structure(s). In some embodiments, structure 225 may be or include integrated circuits and/or other components desired to be coupled to pad 205 through electro-optic device 200.

Electro-optic device 200 may share the benefits of electro-optic device 100 and/or 100′. Electro-optic device 200 may be electrically connected to other components through substrate 204 (e.g. pads 205), bumps 206, and conductive filler 260 in vias 250. Electro-optic device 200 is also mechanically connected to substrate 204. As a result, wire bonding need not be used for electrically connecting to electro-optic device 200. Thus, electro-optic device 200 may be more densely integrated. Further, electro-optic device 200 need not be flip-chip bonded in order to be electrically connected to substrate 204. As a result, electrodes 220 may be distal from the underlying component(s). Operation of electro-optic device 200 may be less likely to affect and/or be affected by components on the underlying substrate. Consequently, performance of electro-optic device 200 and of other components in, on, or coupled with substrate 204 may be improved. In addition, 2.5 and 3D packaging may also be facilitated. Thus, higher density integration of electro-optic device 200 may be facilitated.

FIG. 3 depicts a side view of electro-optic device 300 and the environment in which electro-optic device 300 is integrated. FIG. 3 is not to scale. For clarity, only some components are shown. Electro-optic device 300 is analogous to electro-optic device(s) 100, 100′, and/or 200. Electro-optic device 300 includes TFLC layer 310, electrodes 320, and a substrate structure including substrate 301 and buried oxide (BOX) layer 302 that are analogous to TFLC layer 110, electrodes 120, substrate 101, and BOX layer 102, respectively. Thus, electro-optic layer 310 includes one or more TFLC materials, such as TFLN and/or TFLT. In some embodiments, other electro-optic material(s) may be used may be used in addition to or in lieu of TFLC material(s). Although described as a layer, TFLC layer may include multiple layers. Optical components, such as waveguide(s), are formed in electro-optic layer 330.

Electro-optic device 300 also includes vias 350 having conductive fill 360 that are analogous to vias 150 and/or 150′ and conductive fill 160 and/or 160′. Although not shown, one or more of vias 350 may include a dielectric coating analogous to dielectric coating 162 and/or 162′. Although two vias 350 having particular locations are shown, another (e.g., larger) number of vias are generally present and may be located as desired for electro-optic device 300. Vias 350 extend through not only substrate 301, but also BOX layer 302 and TFLC layer 310. Further, vias 350 may be formed in an analogous manner to vias 150 and/or 150′.

Also shown in FIG. 3 is substate 304 including pads 305 that is analogous to substrate 204 including pads 205. Solder balls 306 and underfill 208 that are analogous to solder balls 206 and underfill 208 are also shown. Thus, electro-optic device 300 is electrically and mechanically integrated with substrate 304. Vias 350 and conductive filler 350 electrically connect electrodes 320 and structure 325 with pads 305 in a manner analogous to vias 250, conductive filler 260, and pads 205. In some embodiments, therefore, via 350 for electrodes 320 may be desired to include a dielectric coating analogous to dielectric coating 162.

Electro-optic device 300 is also shown as including cladding 340, or other encapsulant, and structure 327. Thus, electrodes 320 and TFLC layer 310 may be protected by encapsulant 340. In some embodiments, encapsulant 340 may be omitted. Structure 327 may be analogous to structure 325. However, the portion of TFLC layer 310 near structure 327 has been removed. Via 350 is still considered to extend through TFLC layer 310 because structure 327 may still be electrically connected using conductive filler 360. In some embodiments, structure 327 may be or include integrated circuits and/or other components desired to be coupled to pad 305 through electro-optic device 300.

Electro-optic device 300 may share the benefits of electro-optic device(s) 100, 100′, and/or 200. Electro-optic device 300 may be electrically connected to other components through substrate 304 (e.g. pads 305), bumps 306, and conductive filler 360 in vias 350. Electro-optic device 300 is also mechanically connected to substrate 304. As a result, wire bonding need not be used for electrically connecting to electro-optic device 300. Thus, electro-optic device 300 may be more densely integrated. Further, electro-optic device 300 need not be flip-chip bonded in order to be electrically connected to substrate 304. As a result, electrodes 320 may be distal from the underlying component(s). Operation of electro-optic device 300 may be less likely to affect and/or be affected by components on the underlying substrate. Consequently, performance of electro-optic device 300 and of other components in, on, or coupled with substrate 304 may be improved. In addition, 2.5 and 3D packaging may also be facilitated. Thus, higher density integration of electro-optic device 300 may be facilitated.

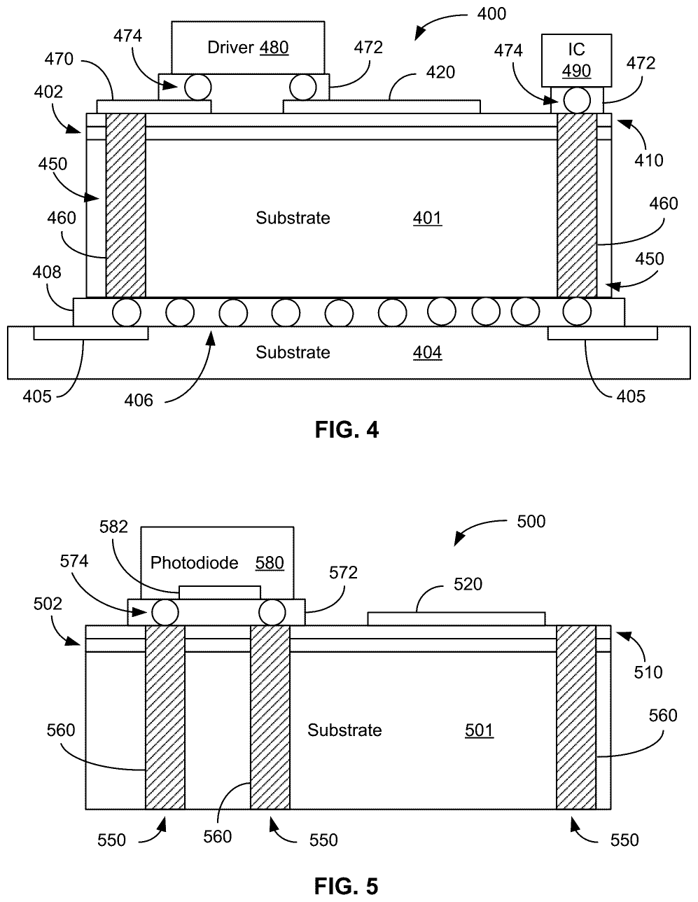

FIG. 4 depicts a side view of electro-optic device 400 and the environment in which electro-optic device 400 is integrated. FIG. 4 is not to scale. For clarity, only some components are shown. Electro-optic device 400 is analogous to electro-optic device(s) 100, 100′, 200, and/or 300. Electro-optic device 400 includes TFLC layer 410, electrodes 420, and a substrate structure including substrate 401 and buried oxide (BOX) layer 402 that are analogous to TFLC layer 110, electrodes 120, substrate 101, and BOX layer 102, respectively. Thus, electro-optic layer 410 includes one or more TFLC materials, such as TFLN and/or TFLT. In some embodiments, other electro-optic material(s) may be used may be used in addition to or in lieu of TFLC material(s). Although described as a layer, TFLC layer may include multiple layers. Optical components, such as waveguide(s), are formed in electro-optic layer 430.

Electro-optic device 400 also includes vias 450 having conductive fill 460 that are analogous to vias 150 and/or 150′ and conductive fill 160 and/or 160′. Although not shown, one or more of vias 450 may include a dielectric coating analogous to dielectric coating 162 and/or 162′. Although two vias 450 having particular locations are shown, another (e.g., larger) number of vias are generally present and may be located as desired for electro-optic device 400. Vias 450 extend through not only substrate 401, but also BOX layer 402 and TFLC layer 410. Further, vias 450 may be formed in an analogous manner to vias 150 and/or 150′. Electro-optic device 400 also includes pad 470. Pad 470 is conductive and may be used to connect to conductive filler 460. In some embodiments, pad 470 is desired to allow for testing of electro-optic device 400 and/or driver 480.

Also shown in FIG. 4 is substate 404 including pads 405 that is analogous to substrate 204 including pads 405. Solder balls 406 and underfill 208 that are analogous to solder balls 206 and underfill 208 are also shown. Thus, electro-optic device 400 is electrically and mechanically integrated with substrate 404. Vias 450 and conductive filler 450 electrically connect electrodes 420 and structure 425 with pads 405 in a manner analogous to vias 250, conductive filler 260, and pads 205. In some embodiments, therefore, via 450 for electrodes 420 may be desired to include a dielectric coating analogous to dielectric coating 162 and/or 162′.

FIG. 4 also depicts integrated circuits 480 and 490. Integrated circuit 480 is a driver. Driver 480 may, for example, be a compact RF driver or other RF component (e.g. differential mode converter GSSG to SSS) that can be placed on electro-optic device 400. Driver 480 is coupled to electro-optic device by solder balls 474. Underfill 472 may fill the gap between driver 480, solder balls 474, and electro-optic device 400. Thus, driver 480 may be used to drive electrodes 420. However, the region of solder balls 474 and underfill 472 may be configured such that it is not aligned with the portion of the electrodes driving the modulator (not shown) and/or the modulator itself (e.g. the portion of the waveguide between the electrodes). In some embodiments, driver 480 is coupled to a pad that is connected with electrodes 420. As a result, the impact on the behavior of electro-optic device 400 may be mitigated. For example, the change in velocity of the microwave mode carried by electrodes 420 and the microwave losses due to underfill 472 and/or solder balls 474 may be limited. Also shown is integrated circuit 490 electrically and mechanically coupled to electro-optic device 400 via solder bumps 474 and underfill 472. Integrated circuit 490 may be a high performance or monitor photodiode and/or another component desired to be integrated with electro-optic device 400. Thus, as used herein with respect to components integrated with electro-optic devices, integrated circuits, such as integrated circuit 490, may include any device that may be mounted on an electro-optic device or on which an electro-optic device is mounted. For example, integrated circuit 490 may be an electrical device or an optical device. Examples of optical device(s) that may be used for integrated circuit 490 include but are not limited to photodiodes, optical amplifiers such as semiconductor optical amplifiers (SOAs) and lasers. Examples of electrical device(s) that may be used for integrated circuit 490 include but are not limited to drivers, micro-controllers, and CMOS ICs with logic and digital signal processing. Thus, although one integrated circuit 490 is shown, multiple integrated circuits (optical and/or electrical devices) may be present.

Using vias 450 and conductive filler 460, driver 480 may be connected to pads 405 of substrate 404. For example, supply voltage(s) may be provided driver 480 and/or or other RF components. Integrated circuit 490 is also coupled to conductive filler 460 and, therefore, pad 405 of substrate 404.

Electro-optic device 400 may share the benefits of electro-optic device(s) 100, 100′, 200, and/or 300. Electro-optic device 400 may be electrically connected to other components through substrate 404 (e.g. pads 405), bumps 406, and conductive filler 460 in vias 450. Electro-optic device 400 is also mechanically connected to substrate 404. As a result, wire bonding need not be used for electrically connecting to electro-optic device 400. Thus, electro-optic device 400 may be more densely integrated. Further, electro-optic device 400 need not be flip-chip bonded in order to be electrically connected to substrate 404. As a result, electrodes 420 may be distal from the underlying component(s). Operation of electro-optic device 400 may be less likely to affect and/or be affected by components on the underlying substrate. Consequently, performance of electro-optic device 400 and of other components in, on, or coupled with substrate 404 may be improved. In addition, 2.5 and 3D packaging may also be facilitated. For example, driver 480 and/or other integrated circuit(s) 490 may be integrated with electro-optic device 400. Integrated circuit(s) 490 may include CMOS integrated circuit(s) with logic and digital signal processing functions (DSP) as well as integrated drivers that connect to modulator portion (not explicitly shown in FIG. 4) of electro-optic device 400. Vias 450 may provide voltage supply or control to integrated circuit 490. Because of the presence of vias 450 and conductive filler 460, integrated circuits 480 and 490 need not be flip-chip bonded to electro-optic device 400, flip-chip bonded to substrate 404, or otherwise directly connected to substrate 404. Thus, issues due to the microwave mode for the electrode signal carried by electrodes 420 may be reduced or eliminated. Thus, higher density integration of electro-optic device 400 may be facilitated.

FIG. 5 depicts a side view of electro-optic device 500 and the environment in which electro-optic device 500 is integrated. FIG. 5 is not to scale. For clarity, only some components are shown. Electro-optic device 500 is analogous to electro-optic device(s) 100, 100′, 200, 300, and/or 400. Electro-optic device 500 includes TFLC layer 510, electrodes 520, and a substrate structure including substrate 501 and buried oxide (BOX) layer 502 that are analogous to TFLC layer 110, electrodes 120, substrate 101, and BOX layer 102, respectively. Thus, electro-optic layer 510 includes one or more TFLC materials, such as TFLN and/or TFLT. In some embodiments, other electro-optic material(s) may be used may be used in addition to or in lieu of TFLC material(s). Although described as a layer, TFLC layer may include multiple layers. Optical components, such as waveguide(s), are formed in electro-optic layer 530. Although not shown, electro-optic device may be used in connection with a substrate analogous to substrates 204, 304, and 404. However, for simplicity, such as substrate is omitted.

Electro-optic device 500 also includes vias 550 having conductive fill 560 that are analogous to vias 150 and/or 150′ and conductive fill 160 and/or 160′. Although not shown, one or more of vias 550 may include a dielectric coating analogous to dielectric coating 162 and/or 162′. Although two vias 550 having particular locations are shown, another (e.g., larger) number of vias are generally present and may be located as desired for electro-optic device 500. Vias 550 extend through not only substrate 501, but also BOX layer 502 and TFLC layer 510. Further, vias 550 may be formed in an analogous manner to vias 150 and/or 150′.

FIG. 5 also depicts integrated circuit 580. Integrated circuit 580 is a photodiode. More specifically, photodiode 580 is a bottom illuminated photodiode. Thus, photodiode 580 includes bottom active region 582. Photodiode 580 is coupled to electro-optic device by solder balls 574. Underfill 572 may fill the gap between photodiode 580, solder balls 574, and electro-optic device 500. Thus, photodiode 580 may be a high performance or monitor photodiode optically coupled with TFLC layer 510 (e.g. to a waveguide of TFLC layer 510). Although the driver analogous to driver 480 is not shown, such a driver may be present and coupled to an underlying substrate (not shown) through conductive material(s) 560 of vias 550. Thus, electrodes 520 may be driven by components of an underlying substrate (not shown) or a driver analogous to driver 480.

Electro-optic device 500 may share the benefits of electro-optic device(s) 100, 100′, 200, 300, and/or 400. Electro-optic device 500 may be electrically connected to other components through a substrate (not shown) and conductive filler 560 in vias 550. As a result, wire bonding need not be used for electrically connecting to electro-optic device 500. Thus, electro-optic device 500 may be more densely integrated. Further, electro-optic device 500 need not be flip-chip bonded in order to be electrically connected to such a substrate. As a result, electrodes 520 may be distal from the underlying component(s). Operation of electro-optic device 500 may be less likely to affect and/or be affected by components on the underlying substrate. Consequently, performance of electro-optic device 500 and of other components in, on, or coupled with the substrate may be improved. In addition, photodiode 580 and/or other integrated circuit(s) (not shown) may be integrated with electro-optic device 500. Because of the presence of vias 550 and conductive filler 560, photodiode 580 need not be wire bonded to electro-optic device 500. Thus, higher density integration of electro-optic device 500 may be facilitated.

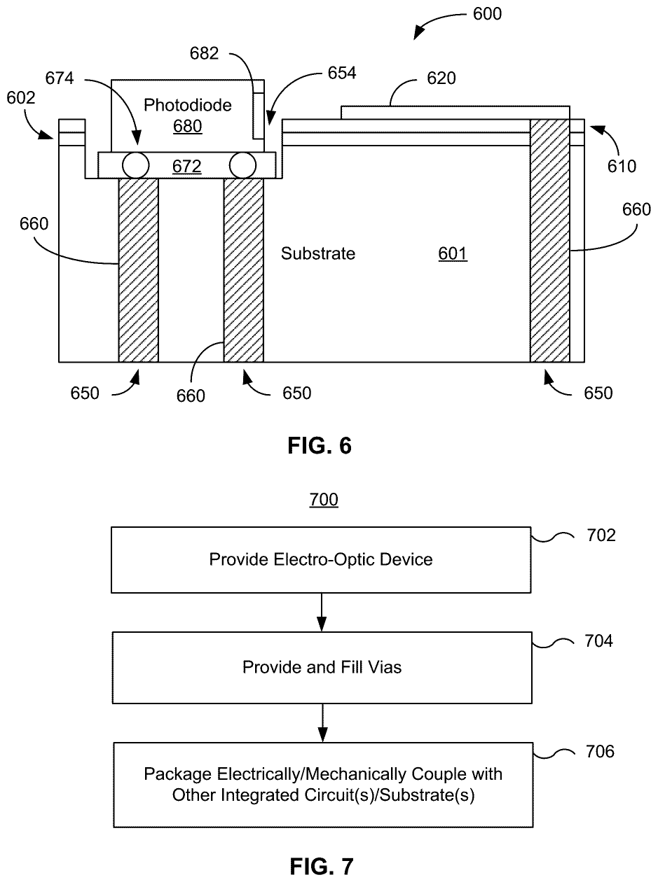

FIG. 6 depicts a side view of electro-optic device 600 and the environment in which electro-optic device 600 is integrated. FIG. 6 is not to scale. For clarity, only some components are shown. Electro-optic device 600 is analogous to electro-optic device(s) 100, 100′, 200, 300, 400, and/or 500. Electro-optic device 600 includes TFLC layer 610, electrodes 620, and a substrate structure including substrate 601 and buried oxide (BOX) layer 602 that are analogous to TFLC layer 110, electrodes 120, substrate 101, and BOX layer 102, respectively. Thus, electro-optic layer 610 includes one or more TFLC materials, such as TFLN and/or TFLT. In some embodiments, other electro-optic material(s) may be used may be used in addition to or in lieu of TFLC material(s). Although described as a layer, TFLC layer may include multiple layers. Optical components, such as waveguide(s), are formed in electro-optic layer 630. Although not shown, electro-optic device may be used in connection with a substrate analogous to substrates 204, 304, and 404. However, for simplicity, such as substrate is omitted.

Electro-optic device 600 also includes vias 650 having conductive fill 660 that are analogous to vias 150 and/or 150′ and conductive fill 160 and/or 160′. Although not shown, one or more of vias 650 may include a dielectric coating analogous to dielectric coating 162 and/or 162′. Although two vias 650 having particular locations are shown, another (e.g., larger) number of vias are generally present and may be located as desired for electro-optic device 600. Vias 650 extend through not only substrate 601, but also BOX layer 602 and TFLC layer 610. Further, vias 650 may be formed in an analogous manner to vias 150.

FIG. 6 also depicts integrated circuit 680. Integrated circuit 680 is a photodiode. More specifically, photodiode 680 is an edge illuminated photodiode. Thus, photodiode 680 includes active region 682 at its edge. Photodiode 680 is coupled to electro-optic device by solder balls 674. Underfill 672 may fill the gap between photodiode 680, solder balls 674, and electro-optic device 600. Thus, photodiode 680 may be a high performance or monitor photodiode optically coupled with TFLC layer 610 (e.g. to a waveguide of TFLC layer 610). In order to align active region 682 with TFLC layer 610, photodiode 680 resides in cavity 654. In some embodiments, cavity 654 may be considered part of via 650. However, cavity 654 may be formed prior to vias 650. Consequently, vias 650 may be aligned to cavity 654.

Electrodes 620 are depicted as being coupled to conductive filler 660 of via 650. Thus, electrodes 620 may be driven by a signal from an underlying substrate (not shown). In some embodiments, a driver analogous to driver 480 may be used to drive electrodes 620.

Electro-optic device 600 may share the benefits of electro-optic device(s) 100, 100′, 200, 300, 400, and/or 500. Electro-optic device 600 may be electrically connected to other components through a substrate (not shown) and conductive filler 660 in vias 650. As a result, wire bonding need not be used for electrically connecting to electro-optic device 600. Thus, electro-optic device 600 may be more densely integrated. Further, electro-optic device 600 need not be flip-chip bonded in order to be electrically connected to such a substrate. As a result, electrodes 620 may be distal from the underlying component(s). Operation of electro-optic device 600 may be less likely to affect and/or be affected by components on the underlying substrate. Consequently, performance of electro-optic device 600 and of other components in, on, or coupled with the substrate may be improved. In addition, photodiode 680 and/or other integrated circuit(s) (not shown) may be integrated with electro-optic device 600. Because of the presence of vias 650 and conductive filler 660, photodiode 680 need not be wire bonded to electro-optic device 600. Thus, higher density integration of electro-optic device 600 may be facilitated.

FIG. 7 is a flow-chart depicting an embodiment of method 700 for providing an electro-optic device and integrating the electro-optic device integrated with an additional component(s). Method 700 is described in the context of processes that may have sub-processes. Although described in a particular order, another order not inconsistent with the description herein may be utilized. For example, in some embodiments, portions of processes may be interleaved. Method 700 is also described in the context of electro-optic device 100. However, method 700 may be used with other electro-optic devices including but not limited to electro-optic devices 100′, 200, 300, 400, 500, and/or 600.

An electro-optic device is provided, at 702. In some embodiments, 702 may include fabricating waveguides and other structures from layer(s) including electro-optic material(s). In addition, structures such as electrodes, cladding, and/or other portions of the electro-optic device may be provided as part of 702. Thus, the electro-optic device formed at 702 may include a substrate, an oxide layer, and a TFLC electro-optic layer having structures formed thereof. The electro-optic device may also include electrodes and/or other structures.

Conductive vias are formed and filled for the elector-optic device, at 704. One or more of the vias formed at 704 extend through the substrate, the oxide layer, and the TFLC electro-optic layer. Also at 704, conductive filler is provided in the vias. In some embodiments, a dielectric coating and/or a cavity having a larger area than the remaining portion of the via are formed as part of 704. Consequently, the electro-optic device provided via 702 and 704 may be more readily integrated.

The electro-optic device may be electrically and/or mechanically coupled with other devices, at 706. For example, the electro-optic device may be coupled with a substrate, such as a PCB via solder bumps and underfill. The electro-optic device may also be coupled to another, underlying integrated circuit. Other integrated circuit(s) and/or structures may also be connected to the top of the electro-optic device at 706.

For example, electro-optic device 100, vias 150, and conductive filler 160 may be formed at 702 and 704. In some embodiments, vias 150 (and optionally conductive filler 160) are completely formed prior to formation of waveguide 130, electrodes 120 and/or other structures. Thus, 704 may occur before 702. In such embodiments, formation of vias 150 and conductive filler 160 is a front end process. In some embodiments, vias 150 are formed after formation of waveguide 130, electrodes 120 and/or other structures. In such embodiments, 702 occurs before 704. Formation of vias 150 and conductive filler 160 is a back end process. In some embodiments, portions of BOX layer 102 may be removed for vias 150 before formation of waveguide 130, electrodes 120 and/or other structures. However, portions of substrate 101 may be removed for vias 150 and conductive filler 160 may be provided after formation of waveguide 130, electrodes 120 and/or other structures. Thus, 702 and 704 may be interleaved. In some embodiments, portions of BOX layer 102 may be removed throughout formation of waveguide 130, electrodes 120 and/or other structures. Thus, 702 and 704 may be carried out in a variety of manners. Electro-optic device 100 including not only TFLC layer 110 and electrodes 120, but also vias 150 and conductive filler 160 may be formed.

Electro-optic device 100 may then be integrated with other devices, at 706. Thus, a substrate (e.g. analogous to substrate 204, 304, and/or 404) and/or integrated circuits (e.g. analogous to driver 480, integrated circuit 490, photodiode 580, and/or photodiode 680) may be combined with electro-optic device 100. Thus, using method 700, integration of TFLC electro-optic devices may be improved.

Although the foregoing embodiments have been described in some detail for purposes of clarity of understanding, the invention is not limited to the details provided. There are many alternative ways of implementing the invention. The disclosed embodiments are illustrative and not restrictive.

What is claimed is:

1. An electro-optic device, comprising:
a substrate;
an oxide layer on the substrate;
a thin film lithium-containing (TFLC) electro-optic layer on the oxide layer, the TFLC electro-optic layer including a waveguide; and
a via extending through the substrate, the oxide layer, and the TFLC electro-optic layer, the via including a conductive filler.

2. The electro-optic device of claim 1, wherein the electro-optic device further includes:
an electrode, electrically coupled with the conductive filler.

3. The electro-optic device of claim 1, wherein the substrate is mounted on an additional substrate including a conductive pad and wherein the conductive filler is electrically connected to the conductive pad.

4. The electro-optic device of claim 1, wherein an integrated circuit (IC) is mounted on the electro-optic device such that the oxide layer is between the substrate and the IC, wherein the IC is electrically connected to the conductive filler.

5. The electro-optic device of claim 4, wherein the IC includes at least one of a driver, a CMOS digital signal processor, or another IC.

6. The electro-optic device of claim 1, wherein a photodiode is mounted on the electro-optic device such that the oxide layer is between the substrate and the photodiode, wherein the photodiode is electrically connected to the conductive filler, the photodiode being an edge-illuminated photodiode, wherein the via has a top portion configured to receive the photodiode, at least part of the top portion of the via being free of the conductive filler, the photodiode residing in the top portion of the via.

7. The electro-optic device of claim 5, wherein the photodiode is a back-coupled photodiode on the electro-optic device.

8. The electro-optic device of claim 1, wherein the oxide layer is at least three micrometers thick and not more than fifteen micrometers thick.

9. The electro-optic device of claim 1, wherein the TFLC electro-optic layer extends across a portion of the oxide layer.

10. An electro-optic device, comprising:
a substrate, the substrate being a silicon substrate having a substrate thickness of at least one hundred micrometers;
an oxide layer on the substrate, the oxide layer being a silicon dioxide layer having a thickness of at least three micrometers and not more than ten micrometers;
a thin film lithium-containing (TFLC) electro-optic layer on at least a portion of the oxide layer, the TFLC electro-optic layer including a waveguide; and
a via extending through the substrate, the oxide layer, and the TFLC electro-optic layer, the via including a conductive filler;
wherein the electro-optic device is mounted on an additional substrate having an electrical connection, the electro-optic device being electrically connected to the electrical connection by the conductive filler.

11. The electro-optic device of claim 10, wherein the electro-optic device further includes:
an electrode, electrically coupled with the conductive filler.

12. The electro-optic device of claim 10, wherein at least one integrated circuit (IC) is mounted on the electro-optic device such that the oxide layer is between the substrate and the IC, the IC being electrically connected to the conductive filler.

13. The electro-optic device of claim 12, wherein the IC includes at least one of a driver, a CMOS digital signal processor, or another IC.

14. The electro-optic device of claim 10, wherein a photodiode is mounted on the electro-optic device such that the oxide layer is between the substrate and the photodiode, wherein the photodiode is electrically connected to the conductive filler, the photodiode being an edge-illuminated photodiode, wherein the via has a top portion configured to receive the photodiode, at least part of the top portion of the via being free of the conductive filler, the photodiode residing in the top portion of the via.

15. A method, comprising:
providing an electro-optic device including a substrate, an oxide layer on the substrate, and a thin film lithium-containing (TFLC) electro-optic layer on the oxide layer, the TFLC electro-optic layer including a waveguide;
providing a via extending through the substrate, the oxide layer, and the TFLC electro-optic layer, the via including a conductive filler.

16. The method of claim 15, wherein the providing the via further includes:
forming the via after the waveguide is provided form the TFLC layer.

17. The method of claim 15, wherein the providing the via further includes:
forming the via before the waveguide is provided form the TFLC layer.

18. The method of claim 15, further comprising:
mounting the electro-optic device on an additional substrate including a conductive pad such that the conductive filler is electrically connected to the conductive pad.

19. The method of claim 15, wherein an integrated circuit (IC) is mounted on the electro-optic device such that the oxide layer is between the substrate and the IC, wherein the IC is electrically connected to the conductive filler.

20. The method of claim 19, wherein providing the via further includes:
forming a top portion configured to receive the IC, at least part of the top portion of the via being free of the conductive filler, the IC residing in the top portion of the via.
